(19) United States
(12) Patent Application Publication
(10) Pub. No.: US 2025/0194348 A1
(43) Pub. Date: Jun. 12, 2025

(54) DISPLAY APPARATUS

(71) Applicant: Samsung Display Co., Ltd., Yongin-si (KR)

(72) Inventors: Jonghwan Cha, Yongin-si (KR); Kinyeng Kang, Yongin-si (KR)

(73) Assignee: Samsung Display Co., Ltd., Yongin-si (KR)

(21) Appl. No.: 18/956,948

(22) Filed: Nov. 22, 2024

(30) Foreign Application Priority Data
Dec. 6, 2023 (KR) 10-2023-0175436

(51) Int. Cl. H10K 59/122; H10K 59/00

(52) U.S. Cl. CPC H10K 59/122; H10K 59/771

(57) ABSTRACT

A display apparatus includes a pixel electrode disposed on a substrate, a pixel defining layer having an opening exposing a central portion of the pixel electrode, an electrically conductive partition wall disposed on the pixel defining layer and having a height of about 500 Å or greater, an intermediate layer disposed on the pixel electrode and including an emission layer and a plurality of common layers, and an opposite electrode disposed on the intermediate layer, wherein at least a portion of the intermediate layer is in direct contact with at least a portion of the electrically conductive partition wall.

### CROSS-REFERENCE TO RELATED APPLICATION

This application claims priority to and benefits of Korean Patent Application No. 10-2023-0175436 under 35 U.S.C. § 119, filed in the Korean Intellectual Property Office on Dec. 6, 2023, the entire contents of which are incorporated herein by reference.

### BACKGROUND

### 1. Technical Field

The disclosure relates to a display apparatus capable of reducing a leakage current and light leakage between sub-pixels.

### 2. Description of the Related Art

Display apparatuses display data as images. Such display apparatuses include a substrate divided into a display area and a peripheral area. Scan lines, data lines, sub-pixels, thin-film transistors, sub-pixel electrodes, and an opposite electrode are disposed in the display area. The scan lines and the data lines are electrically insulated from each other. The thin-film transistors respectively correspond to the sub-pixels and the sub-pixel electrodes are respectively electrically connected to the thin-film transistors. The opposite electrode is commonly provided in the sub-pixels. Various lines configured to transmit electrical signals to the display area, a scan driver, a data driver, a controller, a pad portion, etc. may be provided in the peripheral area.

The display apparatus includes an organic light-emitting display apparatus. The organic light-emitting display apparatus may have stacked layers and emit light for each sub-pixel in the display area.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments provide a display apparatus capable of reducing a leakage current and preventing color mixing between sub-pixels.

Additional aspects will be set forth in part in the description which follows and, in part, will be apparent from the description, or may be learned by practice of the presented embodiments of the disclosure.

According to one or more embodiments, a display apparatus includes a pixel electrode disposed on a substrate, a pixel defining layer having an opening exposing a central portion of the pixel electrode, an electrically conductive partition wall disposed on the pixel defining layer and having a height of about 500 Å or greater, an intermediate layer disposed on the pixel electrode and including an emission layer and a plurality of common layers, and an opposite electrode disposed on the intermediate layer, wherein at least a portion of the intermediate layer is in direct contact with at least a portion of the electrically conductive partition wall.

In an embodiment, in a plan view, the electrically conductive partition wall may surround the opening of the pixel defining layer.

In an embodiment, the electrically conductive partition wall may receive a voltage equal to or lower than a voltage applied to the opposite electrode.

In an embodiment, the electrically conductive partition wall may have a trapezoidal cross-sectional shape.

In an embodiment, an area of an upper surface of the electrically conductive partition wall may be smaller than an area of a lower surface of the electrically conductive partition wall.

In an embodiment, the display apparatus may further include an inorganic insulating layer covering a portion of the electrically conductive partition wall and arranged between the electrically conductive partition wall and the intermediate layer.

In an embodiment, the electrically conductive partition wall may include a plurality of metal layers sequentially stacked each other on the pixel defining layer, the inorganic insulating layer may cover at least a portion of a side surface of the electrically conductive partition wall, and at least some of the plurality of common layers may be in direct contact with at least a portion of an upper surface of the electrically conductive partition wall.

In an embodiment, the pixel electrode may include indium tin oxide (ITO), and at least some of the plurality of metal layers may include aluminum (Al).

In an embodiment, the emission layer may include a lower emission layer and an upper emission layer, which overlap the lower emission layer in a plan view, and the intermediate layer may further include a charge generation layer between the lower emission layer and the upper emission layer.

In an embodiment, the electrically conductive partition wall may include a metal partition wall, and the metal partition wall may include at least one of molybdenum (Mo), titanium (Ti), and aluminum (Al).

According to one or more embodiments, a display apparatus includes a first pixel electrode disposed on a substrate and a second pixel electrode spaced apart from the first pixel electrode on the substrate, a pixel defining layer having a first opening exposing a central portion of the first pixel electrode and a second opening exposing a central portion of the second pixel electrode, an electrically conductive partition wall arranged between the first opening and the second opening, on the pixel defining layer, and receiving a first voltage, a plurality of common layers disposed on the first pixel electrode and the second pixel electrode, and an opposite electrode disposed on the plurality of common layers and receiving a second voltage equal to or higher than the first voltage, wherein the electrically conductive partition wall is in direct contact with a hole injection layer or a hole transport layer, from among the plurality of common layers.

In an embodiment, the electrically conductive partition wall may have a forward tapered cross-sectional shape.

In an embodiment, the electrically conductive partition wall may have a height of about 500 Å or greater.

In an embodiment, in a plan view, the electrically conductive partition wall may surround each of the first opening and the second opening.

In an embodiment, the display apparatus may further include a first lower emission layer disposed on the first pixel electrode, a second lower emission layer disposed on the second pixel electrode, a first upper emission layer disposed on the first lower emission layer, and a second upper emission layer disposed on the second lower emission layer.

In an embodiment, the plurality of common layers may include a 1^{st}-1 common layer disposed below the first lower emission layer and a 1^{st}-2 common layer disposed below the second lower emission layer, and the 1^{st}-1 common layer and the 1^{st}-2 common layer may be integral with each other.

In an embodiment, the display apparatus may further include a first charge generation layer between the first lower emission layer and the first upper emission layer, and a second charge generation layer between the second lower emission layer and the second upper emission layer.

In an embodiment, the electrically conductive partition wall may include a plurality of metal layers sequentially stacked each other on the pixel defining layer.

In an embodiment, the display apparatus may further include an inorganic insulating layer covering the electrically conductive partition wall and exposing at least a portion of an upper surface or at least a portion of a side surface of the electrically conductive partition wall.

In an embodiment, the electrically conductive partition wall may include a metal partition wall, and the metal partition wall may include at least one of molybdenum (Mo), titanium (Ti), and aluminum (Al).

Other aspects, features, and advantages of the disclosure will become better understood through the detailed description, the claims, and the accompanying drawings.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1A is a schematic perspective view of an electronic device according to an embodiment;

FIG. 1B is a schematic plan view of a display apparatus according to an embodiment;

FIG. 2 is a schematic diagram of an equivalent circuit of a pixel circuit included in a display apparatus of FIG. 1B according to an embodiment;

FIG. 3 is a schematic enlarged view of region A in the display apparatus of FIG. 1B;

FIG. 4 is a schematic cross-sectional view of a display apparatus according to an embodiment;

FIGS. 5A and 5B are schematic cross-sectional views of a display apparatus according to an embodiment;

FIGS. 6A to 6C are schematic cross-sectional views of a display apparatus according to an embodiment;

FIGS. 7A to 7C are schematic cross-sectional views of organic light-emitting diodes that may be employed as display elements according to embodiments;

FIG. 8 is a schematic cross-sectional view of a display apparatus according to an embodiment;

FIG. 9 is a schematic cross-sectional view of a display apparatus according to an embodiment; and

FIGS. 10A to 10F are schematic cross-sectional views for describing a process of manufacturing a display apparatus according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Although the terms “first,” “second,” etc. may be used herein to describe various elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10% or 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

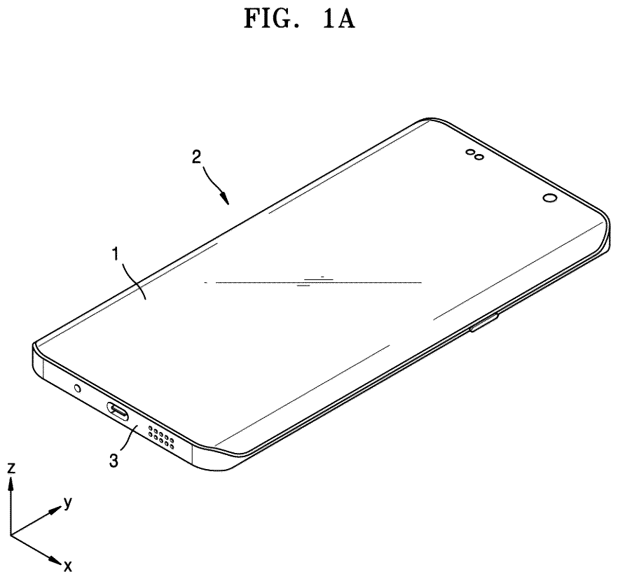

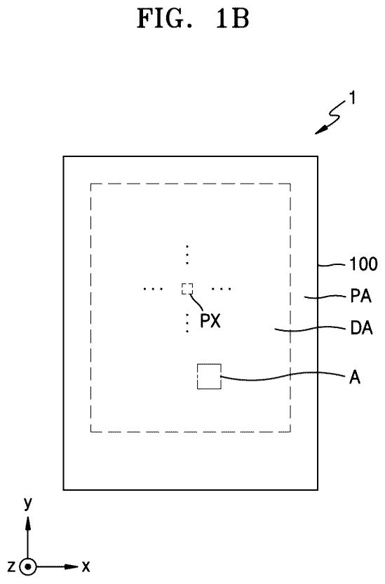

FIG. 1A is a schematic perspective view of an electronic device 2 according to an embodiment. FIG. 1B is a schematic plan view of a display apparatus 1 according to an embodiment.

Referring to FIGS. 1A and 1B, the display apparatus 1 may display moving images or still images. The display apparatus 1 may display images in the electronic device 2, or may input and output data to the electronic device 2.

In FIG. 1A, the display apparatus 1 may be used in a mobile phone. However, the disclosure is not limited thereto. For example, the display apparatus 1 may be used as display screens of portable electronic devices, such as mobile phones, smartphones, tablet personal computers (PCs), mobile communication terminals, electronic organizers, e-books, portable multimedia players (Pumps), navigation systems, ultra mobile PCs (Umps), or the like. For example, the display apparatus 1 may be used as display screens of various products, such as televisions, laptops, monitors, billboards, Internet of things (IoT) devices, or the like.

The display apparatus 1 according to an embodiment may be used in electronic devices such as wearable devices, for example, smart watches, watch phones, glass-type displays, head mounted displays (HMDs), or the like. In an embodiment, the display apparatus 1 may be used as display devices of various electronic devices, for example, dashboards of automobiles, center information displays (CIDs) on the center fascia or dashboards of automobiles, room mirror displays replacing side mirrors of automobiles, and displays on the rear sides of front seats to serve as entertainment devices for backseat passengers of automobiles.

In an embodiment, the display apparatus 1 may be accommodated in a housing 3 of the electronic device 2. The housing 3 may be a cover that protects internal components such as the display apparatus 1 and forms the exterior of the electronic device 2. The display apparatus 1 may be electrically connected to an electronic module of the electronic device 2 and may be driven on the electronic device 2. Detailed description of the display apparatus 1 is provided below.

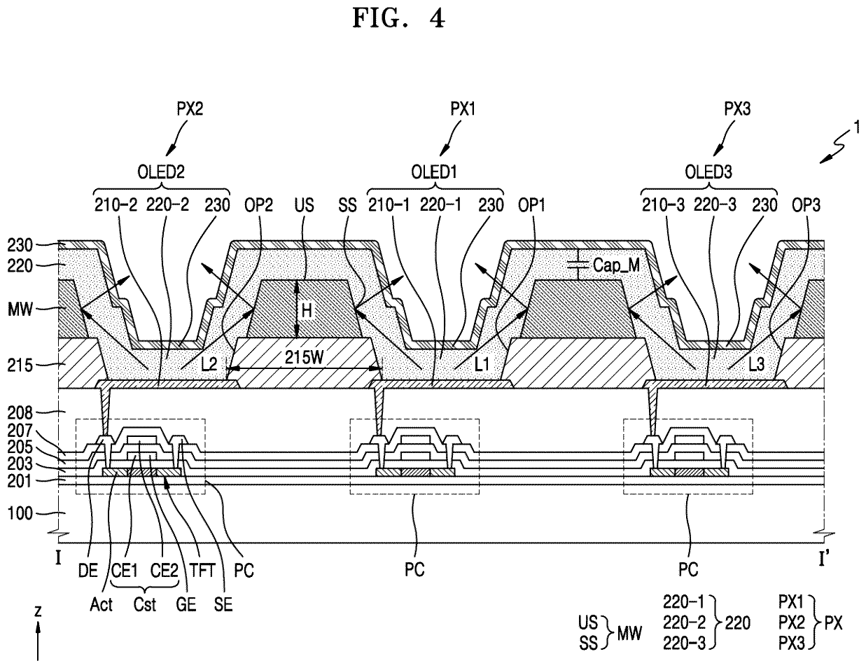

Referring to FIG. 1B, the display apparatus 1 may include a display area DA in which pixels PPX are arranged and a peripheral area PA adjacent to (or outside) the display area DA. For example, the peripheral area PA may surround (e.g., completely surround) the display area DA. A substrate 100 (e.g., refer to FIG. 4) included in the display apparatus 1 may have the display area DA and the peripheral area PA.

Lights (e.g., pieces of light) of colors (e.g., certain or selectable colors) may be emitted from the pixels PPX of the display apparatus 1, and the display apparatus 1 may provide images by using the pieces of light emitted from the pixels PPX. For example, each of the pixels PPX may emit green light, red light, or blue light.

The display area DA may have a polygonal shape including a rectangular shape, as illustrated in FIG. 1B. For example, the display area DA may have a rectangular shape in which a horizontal length is longer than a vertical length, a rectangular shape in which a horizontal length is shorter than a vertical length, a square shape, or the like. However, the disclosure is not limited thereto, and the display area DA may have various shapes, such as an elliptical shape or a circular shape.

The peripheral area PA may be a non-display area in which pixels PPX are not arranged. A driver or the like configured to provide electrical signals or power to the pixels PPX may be arranged in the peripheral area PA. Pads (not shown), to which various electronic devices or a printed circuit board is electrically connected, may be arranged in the peripheral area PA. The pads may be spaced apart from each other in the peripheral area PA and may be electrically connected to a printed circuit board or integrated circuit devices.

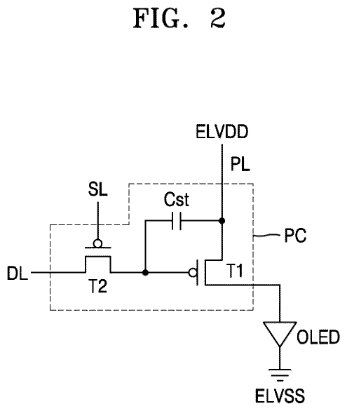

FIG. 2 is a schematic diagram of an equivalent circuit of a pixel circuit PC included in the display apparatus 1 of FIG. 1B according to an embodiment. The pixel circuit PC may be electrically connected to an organic light-emitting diode OLED. Each organic light-emitting diode OLED may correspond to each pixel PPX (e.g., refer to FIG. 1B).

The pixel circuit PC may include a first transistor T1, a second transistor T2, and a storage capacitor Cost. The second transistor T2 may act as a switching transistor and may be electrically connected to a scan line SL and a data line DL. The second transistor T2 may be configured to be turned on in response to a switching signal input from the scan line SL and transmit, to the first transistor T1, a data signal input from the data line DL. The storage capacitor Cost may have an end electrically connected to the second transistor T2 and another end electrically connected to a driving voltage line PL. The storage capacitor Cost may store a voltage difference (e.g., a potential difference) between a voltage received from the second transistor T2 and a driving voltage ELAD supplied to the driving voltage line PL.

The first transistor T1 may act as a driving transistor and may be electrically connected to the driving voltage line PL and the storage capacitor Cost. The first transistor T1 may be configured to control an amount of a driving current flowing from the driving voltage line PL to the organic light-emitting diode OLED according to a voltage value stored in the storage capacitor Cost. The organic light-emitting diode OLED may be configured to emit light having a luminance (e.g., a certain or selectable luminance) according to the driving current. An opposite electrode 230 (e.g., refer to FIG. 4) of the organic light-emitting diode OLED may be configured to receive a common voltage LEVELS.

In FIG. 2, the pixel circuit PC may include two transistors and a storage capacitor. However, the disclosure is not limited thereto. For example, the number of transistors or the number of storage capacitors may be variously changed according to the design of the pixel circuit PC.

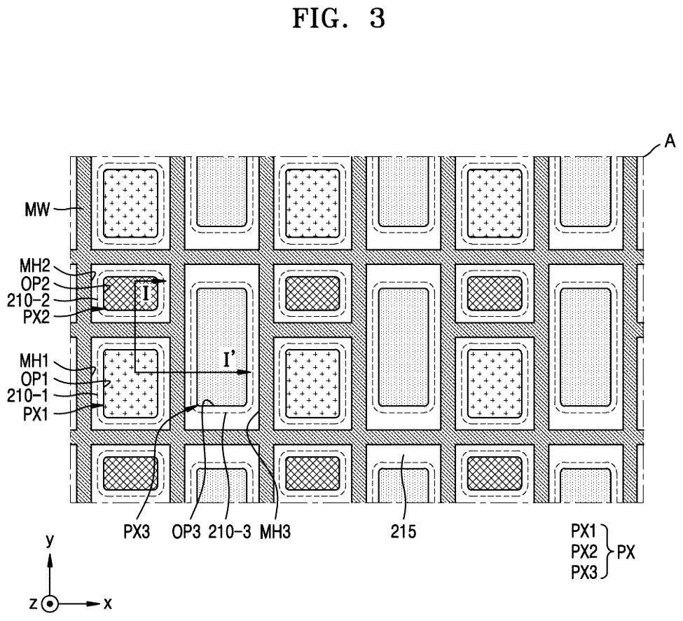

FIG. 3 is a schematic enlarged view of region A in the display apparatus 1 of FIG. 1B. FIG. 3 illustrates a plan view on a pixel defining layer 215 for convenience. However, for convenience of explanation, an electrically conductive partition wall may be disposed on the pixel defining layer 215. The electrically conductive partition wall may include at least one conductive material of metal, metal oxide, graphite, conductive polymer, and the like. In FIG. 3, the electrically conductive partition wall may include a metal partition wall MW.

Referring to FIG. 3, pixels PPX may be arranged in a display area DA (e.g., refer to FIG. 1B) of a substrate 100 (e.g., refer to FIG. 1B). For example, each of the pixels PPX may be a sub-pixel and may include a display element such as an organic light-emitting diode OLED (e.g., refer to FIG. 2). Each pixel PX may emit, for example, green light, red light, or blue light. For example, the pixels PX may include a first pixel PX1 configured to emit green light, a second pixel PX2 configured to emit red light, and a third pixel PX3 configured to emit blue light. The green light may have a wavelength band of about 495 nm to about 580 nm, the red light may have a wavelength band of about 580 nm to about 780 nm, and the blue light may have a wavelength band of about 400 nm to about 495 nm.

A first pixel electrode 210-1 may be included in the first pixel PX1, a second pixel electrode 210-2 may be included in the second pixel PX2, and a third pixel electrode 210-3 may be included in the third pixel PX3. The first pixel electrode 210-1, the second pixel electrode 210-2, and the third pixel electrode 210-3 may be arranged in the display area DA. For example, the first pixel electrode 210-1, the second pixel electrode 210-2, and the third pixel electrode 210-3 may be spaced apart from each other in a plan view. In the specification, the expression “in a plan view” means a case when viewed from a direction perpendicular to the substrate 100. For example, the expression “A and B spaced apart from each other in a plan view” may mean “A and B spaced apart from each other when viewed from a direction perpendicular to the substrate 100.” The first pixel electrode 210-1, the second pixel electrode 210-2, and the third pixel electrode 210-3 may have different sizes, as illustrated in FIG. 3. In another embodiment, the first pixel electrode 210-1, the second pixel electrode 210-2, and the third pixel electrode 210-3 may have a same size.

The pixel defining layer 215 may be disposed on the first pixel electrode 210-1, the second pixel electrode 210-2, and the third pixel electrode 210-3 and may include a first opening OP1, a second opening OP2, and a third opening OP3. For example, the pixel defining layer 215 may include an inner surface defining the first opening OP1, an inner surface defining the second opening OP2, and an inner surface defining the third opening OP3. For example, the first to third openings OP1, OP2, and OP3 may be spaced apart from each other and pass through the pixel defining layer 215.

The first opening OP1 may expose a central portion of the first pixel electrode 210-1, the second opening OP2 may expose a central portion of the second pixel electrode 210-2, and the third opening OP3 may expose a central portion of the third pixel electrode 210-3. The first opening OP1, the second opening OP2, and the third opening OP3 may have different sizes from one another, as illustrated in FIG. 3. In another embodiment, the first opening OP1, the second opening OP2, and the third opening OP3 may have a same size. In FIG. 3, each of the first opening OP1, the second opening OP2, and the third opening OP3 has a rectangular shape. However, the disclosure is not limited thereto. For example, each of the first opening OP1, the second opening OP2, and the third opening OP3 may have a hexagonal shape.

Although not illustrated in FIG. 3, emission layers configured to emit light may be respectively located within the first opening OP1, the second opening OP2, and the third opening OP3 of the pixel defining layer 215. An opposite electrode 230 (e.g., refer to FIG. 4) may be disposed on the emission layers. The pixel electrode, an intermediate layer 220 (e.g., refer to FIG. 4) including the emission layer, and the opposite electrode 230 may be stacked one another. An organic light-emitting diode OLED may include the pixel electrode, the intermediate layer 220, and the opposite electrode 230. Each opening of the pixel defining layer 215 may correspond to each organic light-emitting diode OLED and may define an emission area. For example, the organic light-emitting diode OLED may be disposed in the emission area defined by each of the first to third openings OP1, OP2, and OP3 of the pixel defining layer 215.

For example, an emission layer configured to emit green light may be arranged in the first opening OP1 and the first pixel PX1 may be an emission area defined by the first opening OP1. For example, an emission layer configured to emit red light may be arranged in the second opening OP2 and the second pixel PX2 may be an emission area defined by the second opening OP2. For example, an emission layer configured to emit blue light may be arranged in the third opening OP3 and the third pixel PX3 may be an emission area defined by the third opening OP3. However, the disclosure is not limited thereto. For example, emission layers configured to emit blue light, green light, and white light may be arranged in the first opening OP1, the second opening OP2, and the third opening OP3, respectively. The display apparatus 1 may include a light-emitting panel and a color panel stacked each other in a thickness direction (e.g., a z direction). Blue light, green light, or white light emitted from the emission layer of the light-emitting panel may be transmitted through the color panel. The light may pass through the color panel and be converted into green light, red light, and blue light.

The first opening OP1 and the second opening OP2 may be adjacent to each other in a second direction (e.g., a y direction or a −y direction) intersecting (e.g., crossing) a first direction (e.g., an x direction or a −x direction), and the first opening OP1 and the third opening OP3 may be adjacent to each other in the first direction (e.g., the x direction or the −x direction). For example, the x direction may be opposite to the −x direction, and the y direction may be opposite to the −y direction. In FIG. 3, each of the size of the first opening OP1 and the size of the second opening OP2 adjacent to the first opening OP1 in the second direction (e.g., the y direction or the −y direction) may be smaller than the size of the third opening OP3, and the third opening OP3 and the second opening OP2 may be adjacent to each other in the first direction (e.g., the x direction or the −x direction).

The metal partition wall MW may be disposed on the pixel defining layer 215. For example, when viewed from a direction perpendicular to the substrate 100 (e.g., a z direction or a −z-direction), the metal partition wall MW may be disposed on the pixel defining layer 215 and surround each of the openings (e.g., the first to third openings OP1, OP2, and OP3) included in the pixel defining layer 215. For example, the metal partition wall MW may have a mesh structure. The first opening OP1 may be located within a first metal hole MH1 defined by the metal partition wall MW in a plan view. For example, the second opening OP2 may be located within a second metal hole MH2 defined by the metal partition wall MW in a plan view, and the third opening OP3 may be located within a third metal hole MH3 defined by the metal partition wall MW in a plan view. Accordingly, the metal partition wall MW may be disposed between adjacent ones of the first to third openings OP1, OP2, and OP3 (or the first to third pixels PX1, PX2, and PX3).

In FIG. 3, each of the first metal hole MH1, the second metal hole MH2, and the third metal hole MH3 may have a rectangular shape. However, the disclosure is not limited thereto. For example, the first metal hole MH1, the second metal hole MH2, and/or the third metal hole MH3 may have a polygonal shape including a rectangular shape. For example, each of the first metal hole MH1, the second metal hole MH2, and/or the third metal hole MH3 may have a rectangular shape in which a horizontal length is longer than a vertical length, a rectangular shape in which a horizontal length is shorter than a vertical length, a square shape, or the like. In other embodiments, each of the first metal hole MH1, the second metal hole MH2, and/or the third metal hole MH3 may have various shapes, such as an elliptical shape or a circular shape.

In FIG. 3, the metal partition wall MW may surround (e.g., may completely surround) each of the openings (e.g., the first to third openings OP1, OP2, and OP3) included in the pixel defining layer 215. For example, the metal partition wall MW may completely surround the first opening OP1, the second opening OP2, and the third opening OP3. However, the disclosure is not limited thereto. For example, the metal partition wall MW may partially surround each of the openings (e.g., the first to third openings OP1, OP2, and OP3) included in the pixel defining layer 215. For example, the metal partition wall MW may not surround a side of an opening and surround remaining portions of the opening. Accordingly, in a plan view, the metal partition wall MW may have a U-shape.

In FIG. 3, the pixels PX may be arranged in a stripe type. However, the disclosure is not limited thereto, and the pixels PX may be arranged in various types, such as an RGBG type (e.g., a so-called PENTILE® structure), a diagonal type, or the like.

FIG. 4 is a schematic cross-sectional view of the display apparatus 1 according to an embodiment. For example, FIG. 4 is a schematic cross-sectional view of the display apparatus 1 of FIG. 3 taken along line I-I′ of FIG. 3.

Referring to FIG. 4, the display apparatus 1 according to the embodiment may include a substrate 100. The substrate 100 may include various flexible or bendable materials. For example, the substrate 100 may include glass, metal, polymer resin, or a combination thereof. The substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. However, the disclosure is not limited thereto. In some embodiments, other modifications may be possible. For example, the substrate 100 may have a multilayer structure that includes two layers and a barrier layer disposed between the two layers, the two layers may include polymer resin, and the barrier layer may include an inorganic material. For example, the barrier layer may include at least one of silicon oxide (SiO_{X}), silicon nitride (SiN_{X}), silicon oxynitride (SiO_{X}N_{Y}).

A display element included in a pixel PX and a pixel circuit PC electrically connected to the display element may be disposed on the substrate 100. In FIG. 4, each of the pixels PX may include an organic light-emitting diode OLED (e.g., refer to FIG. 2) as a display element. For example, the organic light-emitting diode OLED may include a first organic light-emitting diode OLED1, a second organic light-emitting diode OLED2, and a third organic light-emitting diode OLED3. For example, a first pixel PX1 may include the first organic light-emitting diode OLED1, a second pixel PX2 may include a second organic light-emitting diode OLED2, and a third pixel PX3 may include a third organic light-emitting diode OLED3.

The pixel circuit PC may be disposed on the substrate 100. The pixel circuits PC of the pixels PX may have a same structure. Thus, detailed description of the same constituent elements may be omitted. The pixel circuit PC may include thin-film transistors TFT and a storage capacitor Cst. For convenience of illustration, a thin-film transistor TFT is illustrated in FIG. 4, and the thin-film transistor TFT may correspond to the first transistor T1 (e.g., refer to FIG. 2) described above.

A buffer layer 201 may be disposed between the thin-film transistor TFT and the substrate 100. The buffer layer 201 may include an inorganic material, such as silicon oxide (SiO_{X}), silicon nitride (SiN_{X}), and/or silicon oxynitride (SiO_{X}N_{Y}). The buffer layer 201 may increase the smoothness of the upper surface of the substrate 100. For example, the buffer layer 201 may prevent or minimize infiltration of impurities from the substrate 100 or the like to a semiconductor layer Act of the thin-film transistor TFT.

Referring to FIG. 4, the thin-film transistor TFT may include the semiconductor layer Act including at least one of amorphous silicon, polycrystalline silicon, an organic semiconductor material, and an oxide semiconductor material. The thin-film transistor TFT may include a gate electrode GE, a source electrode SE, and/or a drain electrode DE. The gate electrode GE may include various conductive materials and have various layered structures. For example, the gate electrode GE may include a molybdenum (Mo) layer and an aluminum (Al) layer. For example, the gate electrode GE may include a TiN_{X} layer, an Al layer, and/or a titanium (Ti) layer. The source electrode SE and the drain electrode DE may include various conductive materials and have various layered structures. For example, each of the source electrode SE and the drain electrode DE may include a Ti layer, an Al layer, and/or a copper (Cu) layer.

A gate insulating layer 203 may be disposed between the semiconductor layer Act and the gate electrode GE. Thus, electrical insulation between the semiconductor layer Act and the gate electrode GE may be secured by the gate insulating layer 203. The gate insulating layer 203 may include an inorganic material, such as silicon oxide (SiO_{X}), silicon nitride, (SiN_{X}), and/or silicon oxynitride (SiO_{X}N_{Y}). In FIG. 4, the gate insulating layer 203 may have a shape corresponding to an entire area of the surface of the substrate 100 and contact holes may be formed in portions (e.g., preset or selectable portions). However, the disclosure is not limited thereto. For example, the gate insulating layer 203 and the gate electrode GE may be patterned to have a same shape in a plan view.

A first interlayer insulating layer 205 may be disposed on the gate electrode GE. The first interlayer insulating layer 205 may include an inorganic material, such as silicon oxide (SiO_{X}), silicon nitride (SiN_{X}), and/or silicon oxynitride (SiO_{X}N_{Y}). The first interlayer insulating layer 205 may have a single-layer or multilayer structure including the material described above. The insulating layer (e.g., the gate insulating layer 203, the first interlayer insulating layer 205, or the like) including the inorganic material described above may be formed by chemical vapor deposition (CVD) or atomic layer deposition (ALD). However, the disclosure is not limited thereto, and the first interlayer insulating layer 205 may have various embodiments and modifications. Detailed description of the first interlayer insulating layer 205 is provided below.

The storage capacitor Cst may include a first capacitor electrode CE1 and a second capacitor electrode CE2 that overlap each other in a plan view. The first interlayer insulating layer 205 may be disposed between the first capacitor electrode CE1 and the second capacitor electrode CE2. The storage capacitor Cst may overlap the thin-film transistor TFT in a plan view. In FIG. 4, the gate electrode GE of the thin-film transistor TFT may be the first capacitor electrode CE1 of the storage capacitor Cst. However, the disclosure is not limited thereto. For example, the storage capacitor Cst may not overlap the thin-film transistor TFT in a plan view. The second capacitor electrode CE2 of the storage capacitor Cst may include a conductive material including at least one of molybdenum (Mo), aluminum (Al), copper (Cu), and titanium (Ti). The second capacitor electrode CE2 of the storage capacitor Cst may include a single layer or multiple layers (structure) including the conductive material described above.

A second interlayer insulating layer 207 may be disposed on the second capacitor electrode CE2 of the storage capacitor Cst. The second interlayer insulating layer 207 may include an inorganic material, such as silicon oxide (SiO_{X}), silicon nitride (SiN_{X}), and/or silicon oxynitride (SiO_{X}N_{Y}). The second interlayer insulating layer 207 may have a single-layer or multilayer structure including the inorganic material described above.

The source electrode SE and the drain electrode DE may be disposed on the second interlayer insulating layer 207. Each of the source electrode SE and the drain electrode DE may include a material having excellent conductivity. Each of the source electrode SE and the drain electrode DE may include a conductive material including at least one of molybdenum (Mo), aluminum (Al), copper (Cu), and titanium (Ti). Each of the source electrode SE and the drain electrode DE may include a single-layer or multilayer (structure) including the conductive material described above. For example, each of the source electrode SE and the drain electrode DE may have a multilayer structure (e.g., a triple layer structure) of Ti/Al/Ti.

However, the disclosure is not limited thereto. For example, the thin-film transistor TFT may have only one of the source electrode SE and the drain electrode DE, or may not have both of the source electrode SE or the drain electrode DE. For example, a thin-film transistor TFT (e.g., a thin-film transistor TFT without the drain electrode DE) may not have the drain electrode DE, another thin-film transistor TFT (e.g., another thin-film transistor TFT without the source electrode SE) electrically connected to the thin-film transistor TFT may not have the source electrode SE, and the semiconductor layers Act of the thin-film transistors TFTs may be electrically connected to each other. The above-described electrical connection structure between the thin-film transistor TFT without the drain electrode DE and the another thin-film transistor TFT without the source electrode SE may have the same effect as a structure between a thin-film transistor TFT having the source electrode SE and another thin-film transistor TFT having the drain electrode DE electrically connected to the source electrode SE of the thin-film transistor TFT. For example, the electrical connection between the thin-film transistor TFT without the drain electrode DE and the another thin-film transistor TFT without the source electrode SE may have the same effect as the electrical connection between the thin-film transistor TFT having the drain electrode DE and the another thin-film transistor TFT having the source electrode SE.

Referring to FIG. 4, a planarization layer 208 may cover the thin-film transistor TFT and the storage capacitor Cst. The planarization layer 208 may include an organic insulating material. For example, the planarization layer 208 may include at least one of photoresist, benzocyclobutene (BCB), polyimide, hexamethyldisiloxane (HMDSO), polymethylmethacrylate (PMMA), polystyrene, polymer derivatives having a phenolic group, acrylic polymer, imide-based polymer, aryl ether-based polymer, amide-based polymer, fluorine-based polymer, p-xylene-based polymer, and vinyl alcohol-based polymer. However, the disclosure is not limited thereto, and the planarization layer 208 may include various suitable materials. Although not illustrated in FIG. 4, a third interlayer insulating layer (not shown) may be further disposed below the planarization layer 208. The third interlayer insulating layer may include at least one inorganic material of silicon oxide (SiO_{X}), silicon nitride (SiN_{X}), and silicon oxynitride (SiO_{X}N_{Y}).

FIG. 4 illustrates the pixel circuit PC formed on the substrate 100. For example, the buffer layer 201 may be disposed on the substrate 100. The semiconductor layer Act may be disposed on the buffer layer 201. The gate insulating layer 203 may be disposed on the semiconductor layer Act. The gate electrode GE may be disposed on the gate insulating layer 203. The first interlayer insulating layer 205 may be disposed on the gate electrode GE. The second capacitor electrode CE2 may be disposed on the first interlayer insulating layer 205. The second interlayer insulating layer 207 may be disposed on the second capacitor electrode CE2. The source electrode SE and the drain electrode DE may be disposed on the second interlayer insulating layer 207. The planarization layer 208 may be disposed on the source electrode SE and the drain electrode DE. Accordingly, the pixel circuit PC may be formed on the substrate 100.

However, the disclosure is not limited thereto. For example, the display apparatus 1 may include a complementary metal-oxide semiconductor (CMOS) circuit formed by using a semiconductor process. The organic light-emitting diode OLED may be electrically connected to a CMOS circuit. For example, the organic light-emitting diode OLED may be electrically connected to transistors and capacitors formed by using a semiconductor process. The substrate 100 may include a silicon substrate (e.g., a silicon semiconductor substrate). For example, the substrate 100 may be a silicon wafer. The silicon wafer may be a monocrystalline silicon wafer, a polycrystalline silicon wafer, or an amorphous silicon wafer.

The first organic light-emitting diode OLED1, the second organic light-emitting diode OLED2, and the third organic light-emitting diode OLED3 may be spaced apart from each other on the planarization layer 208. The first organic light-emitting diode OLED1, the second organic light-emitting diode OLED2, and the third organic light-emitting diode OLED3 may emit pieces of light of different colors. For example, the first organic light-emitting diode OLED1 may emit green light, the second organic light-emitting diode OLED2 may emit red light, and the third organic light-emitting diode OLED3 may emit blue light.

The first organic light-emitting diode OLED1 may include a first pixel electrode 210-1, a first intermediate layer 220-1, and an opposite electrode 230. The second organic light-emitting diode OLED2 may include a second pixel electrode 210-2, a second intermediate layer 220-2, and an opposite electrode 230. The third organic light-emitting diode OLED3 may include a third pixel electrode 210-3, a third intermediate layer 220-3, and an opposite electrode 230. The opposite electrode 230 may extend (or be integrally provided) across an entire surface of the display apparatus 1 and may be commonly provided in organic light-emitting diodes. For example, the opposite electrode 230 may extend across the first organic light-emitting diode OLED1, the second organic light-emitting diode OLED2, and the third organic light-emitting diode OLED3.

Each of the first pixel electrode 210-1, the second pixel electrode 210-2, and the third pixel electrode 210-3 may include a transmissive conductive layer and a reflective layer. The transmissive conductive layer may include a transmissive conductive oxide, such as indium tin oxide (ITO), In₂O₃, or indium zinc oxide (IZO), and the reflective layer may include metal, such as Al or Ag. However, the disclosure is not limited thereto. For example, each of the first pixel electrode 210-1, the second pixel electrode 210-2, and the third pixel electrode 210-3 may have a triple-layer structure of ITO/Ag/ITO. In an embodiment, each of the first pixel electrode 210-1, the second pixel electrode 210-2, and the third pixel electrode 210-3 may be a single layer or multiple layers (structure) including TiN_{X}.

The first pixel electrode 210-1, the second pixel electrode 210-2, and the third pixel electrode 210-3 may be in contact with one of the source electrode SE and the drain electrode DE. Thus, each of the first pixel electrode 210-1, the second pixel electrode 210-2, and the third pixel electrode 210-3 may be electrically connected to the thin-film transistor TFT, as illustrated in FIG. 4. For example, each of the first pixel electrode 210-1, the second pixel electrode 210-2, and the third pixel electrode 210-3 may be in contact with one of the source electrode SE and the drain electrode DE through a contact hole formed in the planarization layer 208.

A pixel defining layer 215 may be disposed on the planarization layer 208. Since the pixel defining layer 215 has an opening corresponding to the pixel PX (e.g., an opening exposing at least the central portion of the pixel electrode), the pixel defining layer 215 may define the pixel PX. For example, the pixel defining layer 215 may have a first opening OP1, a second opening OP2, and a third opening OP3. The first opening OP1 may expose the central portion of the first pixel electrode 210-1, the second opening OP2 may expose the central portion of the second pixel electrode 210-2, and the third opening OP3 may expose the central portion of the third pixel electrode 210-3.

In FIG. 4, the pixel defining layer 215 may increase a distance between an edge of the first pixel electrode 210-1 and the opposite electrode 230 disposed on the first pixel electrode 210-1. For example, the pixel defining layer 215 may increase a distance between an edge of the second pixel electrode 210-2 and the opposite electrode 230 disposed on the second pixel electrode 210-2 and may increase a distance between an edge of the third pixel electrode 210-3 and the opposite electrode 230 disposed on the third pixel electrode 210-3. Thus, an electric arc or the like may be prevented from occurring at the edges of the first pixel electrode 210-1, the edge of the second pixel electrode 210-2, or the edge of the third pixel electrode 210-3. The pixel defining layer 215 may include an organic material, such as polyimide or hexamethyldisiloxane (HMDSO). In an embodiment, the pixel defining layer 215 may include, for example, an inorganic material, such as silicon oxide (SiO_{X}) or silicon nitride (SiN_{X}). However, the disclosure is not limited thereto.

An intermediate layer 220 may be disposed on the first pixel electrode 210-1, the second pixel electrode 210-2, and the third pixel electrode 210-3. The intermediate layer 220 may include a first intermediate layer 220-1 corresponding to the first pixel PX1, a second intermediate layer 220-2 corresponding to the second pixel PX2, and a third intermediate layer 220-3 corresponding to the third pixel PX3. The first intermediate layer 220-1 may be disposed on the first pixel electrode 210-1. The second intermediate layer 220-2 may be disposed on the second pixel electrode 210-2. The third intermediate layer 220-3 may be disposed on the third pixel electrode 210-3.

The first to third intermediate layers 220-1 to 220-3 may respectively include emission layers configured to emit pieces of light in different wavelength bands. For example, the first intermediate layer 220-1 may include a first emission layer configured to emit green light. The second intermediate layer 220-2 may include a second emission layer configured to emit red light. The third intermediate layer 220-3 may include a third emission layer configured to emit blue light. The green light may be light in a wavelength band of about 495 nm to about 580 nm, the red light may be light in a wavelength band of about 580 nm to about 780 nm, and the blue light may be light in a wavelength band of about 400 nm to about 495 nm.

Thus, each of the first to third emission layers may include a high molecular weight organic material or a low molecular weight organic material that emits light of a color (e.g., a certain or selectable color). For example, the first emission layer may be formed by using, for example, a green dopant in a host material (e.g., a certain or selectable host material). The second emission layer may be formed by using, for example, a red dopant in a host material (e.g., a certain or selectable host material). The third emission layer may be formed by using, for example, a blue dopant in a host material (e.g., a certain or selectable host material).

The intermediate layer 220 may include common layers. At least some common layers may extend across (or be integrally formed in) the first organic light-emitting diode OLED1, the second organic light-emitting diode OLED2, and the third organic light-emitting diode OLED3. For example, a common layer (e.g., a certain or selectable common layer) included in the first intermediate layer 220-1, a common layer (e.g., a certain or selectable common layer) included in the second intermediate layer 220-2, and a common layer (e.g., a certain or selectable common layer) included in the third intermediate layer 220-3 may be arranged continuously. For example, the first intermediate layer 220-1, the second intermediate layer 220-2, and the third intermediate layer 220-3 may form a same common layer. For convenience of explanation, in FIG. 4 the intermediate layer 220 may be continuously arranged in the first organic light-emitting diode OLED1, the second organic light-emitting diode OLED2, and the third organic light-emitting diode OLED3.

The opposite electrode 230 may be arranged in the display area DA (e.g., refer to FIG. 1B) and may cover the display area DA. For example, the opposite electrode 230 may extend across (or be integrally formed in) the first organic light-emitting diode OLED1, the second organic light-emitting diode OLED2, and the third organic light-emitting diode OLED3 and may correspond to the first pixel electrode 210-1, the second pixel electrode 210-2, and the third pixel electrode 210-3. For example, the opposite electrode 230 may overlap all of the first pixel electrode 210-1, the second pixel electrode 210-2, and the third pixel electrode 210-3 in a plan view. The opposite electrode 230 may cover the peripheral area PA (e.g., refer to FIG. 1B) and the display area DA.

The opposite electrode 230 may include a transmissive conductive layer including, e.g., ITO, In₂O₃, or IZO, and may also include a semi-transmissive layer including metal, such as Al or Ag. For example, the opposite electrode 230 may be a semi-transmissive layer including Mg or Ag. Although not illustrated in FIG. 4, a capping layer (not shown) may be disposed on the opposite electrode 230. For example, the capping layer may include a material selected from an organic material, an inorganic material, and any mixture thereof. The capping layer may include a single layer or multiple layers (structure). In other embodiments, a LiF layer may be disposed on the capping layer.

However, a spacing (e.g., a distance) between adjacent ones of the pixels (e.g., the first to third pixels PX1, PX2, and PX3) may be determined according to a width 215W of the pixel defining layer 215. The width 215W of the pixel defining layer 215 may be about 20 μm or smaller. In a high-resolution display apparatus, the width 215W of the pixel defining layer 215 may be about 2 μm or smaller. In case that the resolution of the display apparatus increases, light emitted from an emission layer of a pixel may travel to an adjacent pixel. Thus, color of the pixel may be mixed with color of the adjacent pixel, and an unintended current may be applied to the adjacent pixel through a common layer. However, the display apparatus 1 according to an embodiment may include the metal partition wall MW between the pixel defining layer 215 and the intermediate layer 220, and light leakage to adjacent pixels and leakage current flowing between adjacent pixels may be prevented.

The metal partition wall MW may be disposed on the pixel defining layer 215. The metal partition wall MW may be disposed between the pixel defining layer 215 and the intermediate layer 220. The metal partition wall MW may define an upper surface US that is parallel to the upper surface of the substrate 100 and is in contact with the intermediate layer 220, and a side surface SS that is inclined at an angle (e.g., a certain or selectable angle) with respect to the upper surface of the substrate 100. The side surface SS of the metal partition wall MW may define metal holes MH1, MH2, and MH3 of FIG. 3.

The metal partition wall MW may be in contact with (e.g., be in direct contact with) at least a portion of the intermediate layer 220. For example, the metal partition wall MW may be in contact with (e.g., be in direct contact with) at least some common layers included in the intermediate layer 220. The lowermost layer among the common layers included in the intermediate layer 220 may be in direct contact with the metal partition wall MW. At least some common layers included in the intermediate layer 220 may extend (e.g., be continuously disposed) on the upper surface US and the side surface SS of the metal partition wall MW. The metal partition wall MW may be disposed between the first opening OP1 and the second opening OP2, between the second opening OP2 and the third opening OP3, and between the first opening OP1 and the third opening OP3. The metal partition wall MW may surround the first opening OP1, the second opening OP2, and the third opening OP3.

A height H of the metal partition wall MW may be about 500 Å or greater. The height H of the metal partition wall MW may be the height in a direction perpendicular to the substrate 100 and refer to the height of the display apparatus 1 in a thickness direction. Since the height H of the metal partition wall MW is about 500 Å or greater, first light L1 emitted from the first intermediate layer 220-1 of the first pixel PX1 in a high-resolution display apparatus may be prevented from traveling to the second pixel PX2 and the third pixel PX3 adjacent to the first pixel PX1. For example, second light L2 emitted from the second intermediate layer 220-2 of the second pixel PX2 may be prevented from traveling to the first pixel PX1 and third pixel PX3 adjacent to the second pixel PX2, and third light L3 emitted from the third intermediate layer 220-3 of the third pixel PX3 may be prevented from traveling to the first pixel PX1 and the second pixel PX2 adjacent to the third pixel PX3. In an embodiment, since the height H of the metal partition wall MW is about 10,000 Å or smaller, the thickness of the display apparatus 1 may be prevented from increasing.

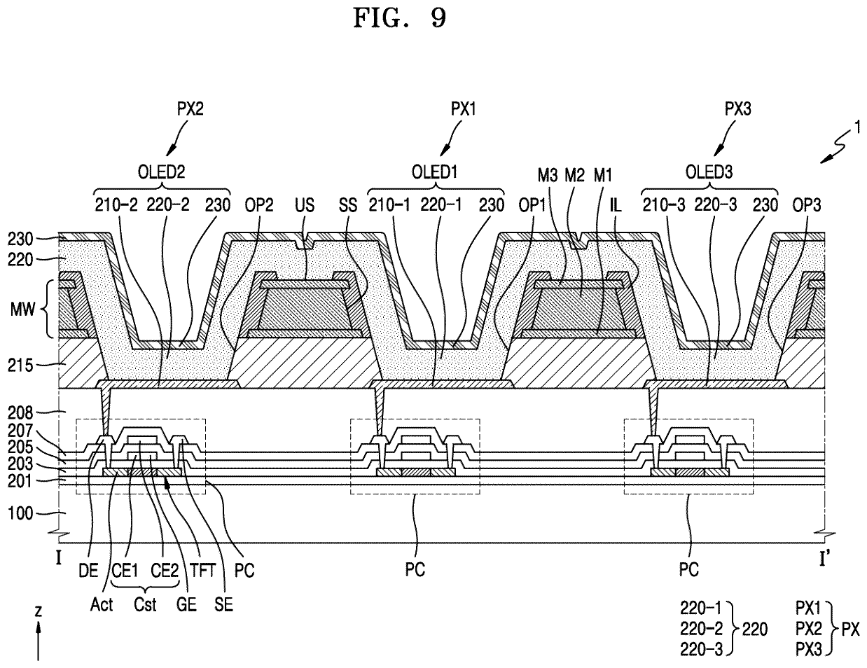

The metal partition wall MW may have a single-layer or multilayer structure. In FIG. 4, the metal partition wall MW may have a single layer structure. However, the disclosure is not limited thereto. For example, the metal partition wall MW may have a multilayer structure in which metal layers are stacked each other on the pixel defining layer 215. Detailed description of the metal partition wall MW having the multilayer structure is provided below with reference to FIG. 9. The metal layers may have different material compositions.

The metal partition wall MW may have a trapezoidal cross-sectional shape. The area of the upper surface US of the metal partition wall MW may be smaller than the area of the lower surface of the metal partition wall MW. The metal partition wall MW may have a forward tapered cross-sectional side surface. Referring to FIGS. 3 and 4, in an embodiment, in case that the metal partition wall MW includes the first metal hole MH1, the second metal hole MH2, and the third metal hole MH3, the side surfaces SS of the metal partition wall MW defining the first metal hole MH1, the second metal hole MH2, and the third metal hole MH3 may have a forward tapered angle.

The metal partition wall MW may include a material with high reflectivity. For example, the metal partition wall MW may include at least one of aluminum (Al), silver (Ag), molybdenum (Mo), and titanium (Ti). The metal partition wall MW may modify a traveling path of light by reflecting light emitted from a pixel in a direction toward an adjacent pixel back in a direction toward the pixel. For example, the metal partition wall MW may guide the light in the direction toward the pixel. For example, the first light L1 emitted from the first pixel PX1 toward the second pixel PX2 and/or the third pixel PX3 adjacent to the first pixel PX1 may be reflected from the forward tapered side surface SS of the metal partition wall MW toward the first pixel PX1. For example, the second light L2 emitted from the second pixel PX2 toward the first pixel PX1 and/or the third pixel PX3 adjacent to the second pixel PX2 may be reflected from the forward tapered side surface SS of the metal partition wall MW toward the second pixel PX2. The third light L3 emitted from the third pixel PX3 toward the first pixel PX1 and/or the second pixel PX2 adjacent to the third pixel PX3 may be reflected from the forward tapered side surface SS of the metal partition wall MW toward the third pixel PX3. Accordingly, the color purity of the display apparatus 1 may be improved.

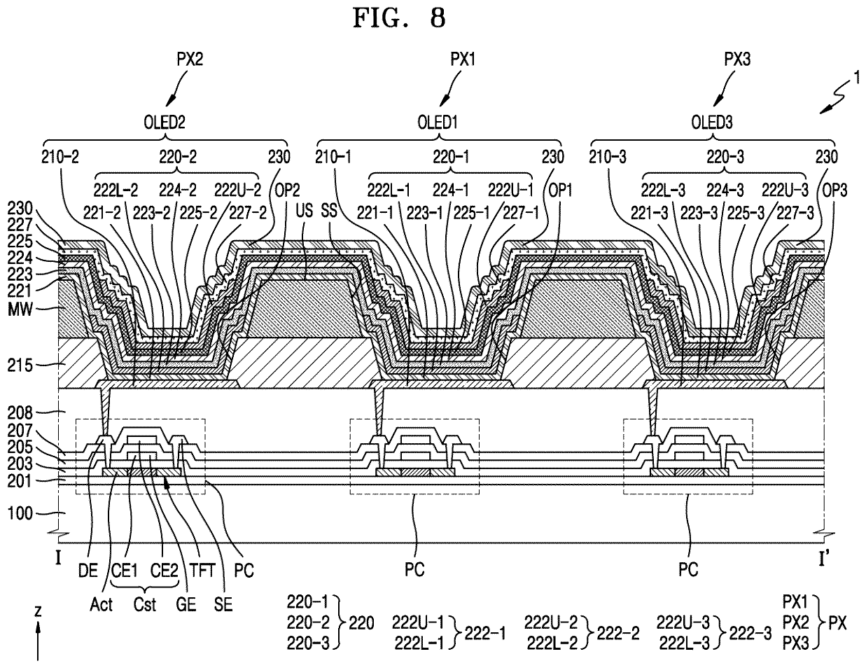

An auxiliary voltage (hereinafter, a first voltage) that is equal to or lower than a voltage (hereinafter, a second voltage) applied to the opposite electrode 230 may be applied to the metal partition wall MW. In an embodiment, the display apparatus 1 may further include an auxiliary electrode (not shown) configured to supply an auxiliary voltage to the metal partition wall MW. The metal partition wall MW may be electrically connected to the auxiliary electrode. For example, the metal partition wall MW may be electrically connected to the auxiliary electrode through a contact hole (not shown) provided in the pixel defining layer 215. Since the auxiliary voltage that is equal to or lower than the voltage applied to the opposite electrode 230 is applied to the metal partition wall MW, a leakage current flowing between the adjacent pixels may be reduced. For example, the first voltage may be equal to or lower than the second voltage, and the leakage current flowing between the adjacent pixels may be reduced. Detailed description of the disclosure is provided below with reference to FIG. 8.

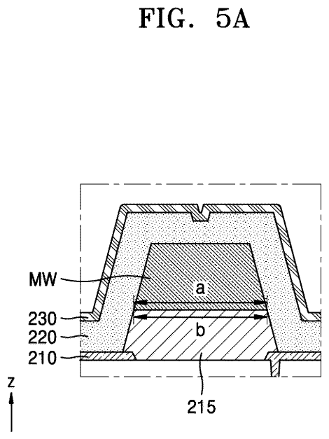

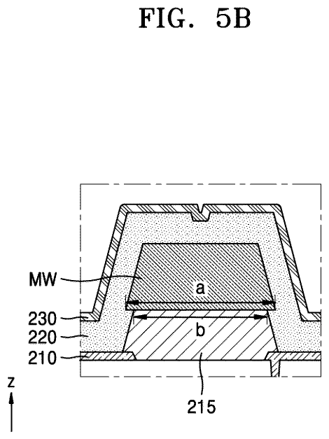

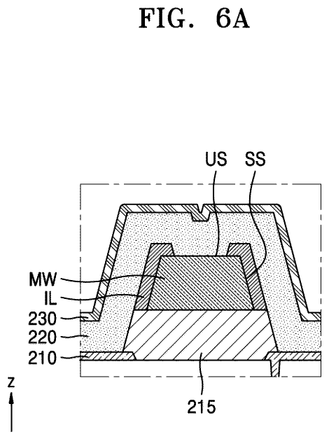

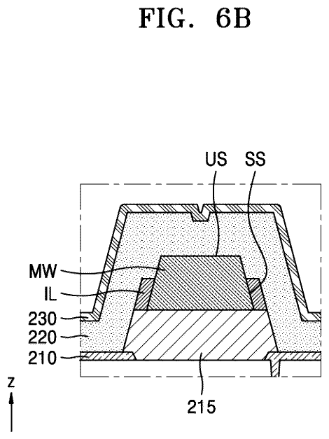

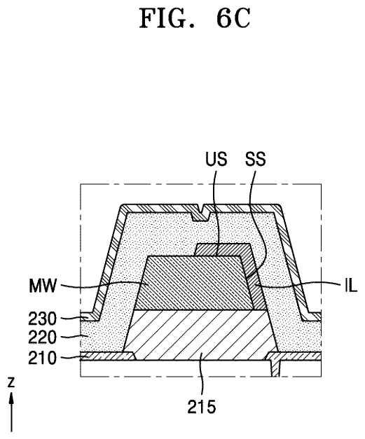

FIGS. 5A and 5B are schematic cross-sectional views of a display apparatus according to an embodiment. FIGS. 6A to 6C are schematic cross-sectional views of a display apparatus according to an embodiment.

In FIG. 4, the width of the lower surface of the metal partition wall MW may be smaller than the width of the upper surface of the pixel defining layer 215. However, the disclosure is not limited thereto. For example, referring to FIG. 5A, a width ‘a’ of the lower surface of the metal partition wall MW may be equal to a width b of the upper surface of the pixel defining layer 215 (e.g., a=b). In other embodiments, referring to FIG. 5B, a width ‘a’ of the lower surface of the metal partition wall MW may be greater than a width b of the upper surface of the pixel defining layer 215 (e.g., a>b). In an embodiment, in case that the pixel defining layer 215 includes an organic layer, a connection portion between the metal partition wall MW and the pixel defining layer 215 may have an undercut shape due to the difference in etch rate between the metal partition wall MW, which is a metal layer, and the organic layer, as illustrated in FIG. 5B. In an embodiment, even when the pixel defining layer 215 includes an inorganic layer, a connection portion between the metal partition wall MW and the pixel defining layer 215 may have an undercut shape in an etching process.

Referring to FIGS. 6A to 6C, the display apparatus according to an embodiment may include an inorganic insulating layer IL that covers at least a portion of the metal partition wall MW. The inorganic insulating layer IL may be disposed between the metal partition wall MW and the intermediate layer 220. The inorganic insulating layer IL may separate at least a portion of the upper surface US and/or at least a portion of the side surface SS of the metal partition wall MW from the intermediate layer 220.

In an embodiment, referring to FIG. 6A, the inorganic insulating layer IL may cover an entire area of the side surface SS of the metal partition wall MW and a portion (e.g., an edge portion) of the upper surface US of the metal partition wall MW. In other embodiments, referring to FIG. 6B, the inorganic insulating layer IL may cover a lower side of the side surface SS of the metal partition wall MW and expose an upper side of the side surface SS of the metal partition wall MW and an entire area of the upper surface US of the metal partition wall MW. In other embodiments, referring to FIG. 6C, the inorganic insulating layer IL may cover only a side of the side surface SS of the metal partition wall MW and a portion of the upper surface US of the metal partition wall MW.

The surface of the metal partition wall MW, which is covered by the inorganic insulating layer IL, may be spaced apart from the intermediate layer 220. The surface of the metal partition wall MW, which is exposed without being covered by the inorganic insulating layer IL, may be in direct contact with the intermediate layer 220. In FIG. 6A, the intermediate layer 220 may be in direct contact with a portion (e.g., a central portion) of the upper surface US of the metal partition wall MW. In FIG. 6B, the intermediate layer 220 may be in direct contact with an entire area of the upper surface US and an upper portion of the side surface SS of the metal partition wall MW. In FIG. 6C, the intermediate layer 220 may be in direct contact with another side of the side surface SS and a portion of the upper surface US of the metal partition wall MW. Thus, the position at which the metal partition wall MW is in direct contact with the intermediate layer 220 may be determined according to the position of the inorganic insulating layer IL.

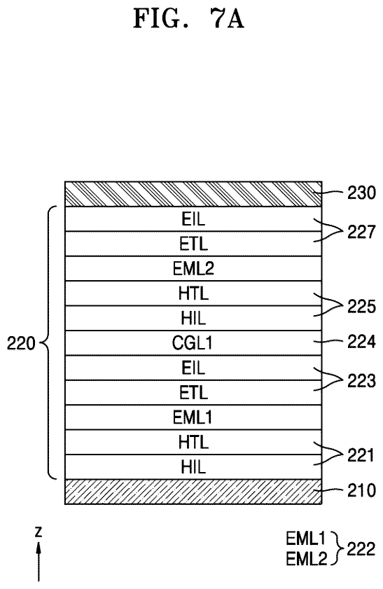

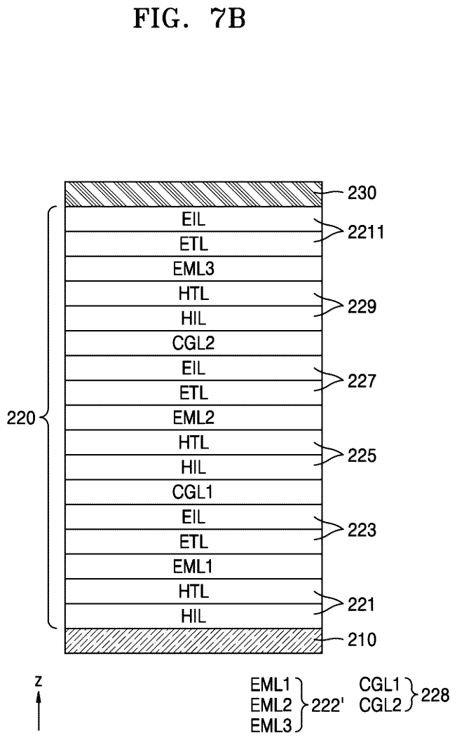

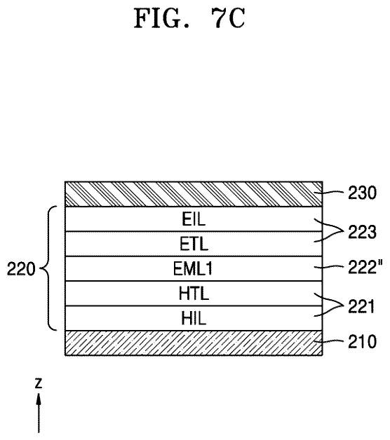

FIGS. 7A to 7C are schematic cross-sectional views of organic light-emitting diodes that may be employed as display elements, according to embodiments.

Referring to FIG. 7A, an intermediate layer 220 of the organic light-emitting diode according to an embodiment may include an emission layer 222, a charge generation layer 224, and common layers. The common layers may include a first common layer 221, a second common layer 223, a third common layer 225, and a fourth common layer 227.

The emission layer 222 may include a first sub-emission layer EML1 and a second sub-emission layer EML2, which are stacked each other and spaced apart from each other. Holes and electrons may be combined with each other in the emission layer 222, and light may be emitted from the emission layer 222. The first sub-emission layer EML1 and the second sub-emission layer EML2 may include materials that emit a same color or materials that emit different colors.

The charge generation layer 224 may help the movement of electrons and holes. The charge generation layer 224 may include layers including an N-type charge generation layer and a P-type charge generation layer. The N-type charge generation layer may include an N-type dopant material and an N-type host material, and the P-type charge generation layer may include a P-type dopant material and a P-type host material.

The first common layer 221 may overlap the charge generation layer 224 in a plan view. The first common layer 221 may include a hole injection layer HIL and a hole transport layer HTL. The hole injection layer HIL may be a layer into which holes transported from a pixel electrode 210 or the charge generation layer 224 are injected. The hole transport layer HTL may transport, to the emission layer 222, the holes transferred from the hole injection layer HIL.

The second common layer 223 may overlap the charge generation layer 224 in a plan view. The second common layer 223 may include an electron transport layer ETL and an electron injection layer EIL. The electron injection layer EIL may be a layer into which electrons transported from an opposite electrode 230 or the charge generation layer 224 are injected. The electron transport layer ETL may transport, to the emission layer 222, the electrons transported from the electron injection layer EIL. For example, the hole injection layer HIL, the hole transport layer HTL, the first sub-emission layer EML1, the electron transport layer ETL, and the electron injection layer EIL may be stacked one another (e.g., stacked in sequence) and emit light.

The third common layer 225 and the first common layer 221 may have a same stacked structure. The fourth common layer 227 and the second common layer 223 may have a same stacked structure. Accordingly, the hole injection layer HIL, the hole transport layer HTL, the second sub-emission layer EML2, the electron transport layer ETL, and the electron injection layer EIL may be stacked one another (e.g., stacked in sequence) and emit light.

In the embodiments, the hole injection layer HIL, the hole transport layer HTL, the first sub-emission layer EML1, the electron transport layer ETL, the electron injection layer EIL, the charge generation layer 224, the hole injection layer HIL, the hole transport layer HTL, the second sub-emission layer EML2, the electron transport layer ETL, the electron injection layer EIL, and the opposite electrode 230 may be stacked one another (e.g., stacked in sequence) on the pixel electrode 210.

In FIG. 7A, each of the second common layer 223 and the fourth common layer 227 may include the electron transport layer ETL and the electron injection layer EIL. However, the disclosure is not limited thereto, and each of the second common layer 223 and the fourth common layer 227 may not include the electron injection layer EIL.

Referring to FIG. 7B, an intermediate layer 220 of the organic light-emitting diode according to an embodiment may include an emission layer 222′ (e.g., a first sub-emission layer EML1, a second sub-emission layer EML2, and a third sub-emission layer EML3), a charge generation layer 228, and common layers. The common layers may include a first common layer 221, a second common layer 223, a third common layer 225, a fourth common layer 227, a fifth common layer 229, and a sixth common layer 2211.

The emission layer 222′ may include a first sub-emission layer EML1, a second sub-emission layer EML2, and a third sub-emission layer EML3, which are stacked one another and spaced apart from each other. The first sub-emission layer EML1, the second sub-emission layer EML2, and the third sub-emission layer EML3 may include materials that emit a same color. In other embodiments, the first sub-emission layer EML1, the second sub-emission layer EML2, and the third sub-emission layer EML3 may include materials that emit different colors.

The charge generation layer 228 may include a first sub-charge generation layer CGL1 and a second sub-charge generation layer CGL2. Each of the first sub-charge generation layer CGL1 and the second sub-charge generation layer CGL2 may include layers including an N-type charge generation layer and a P-type charge generation layer. The N-type charge generation layer may include an N-type dopant material and an N-type host material, and the P-type charge generation layer may include a P-type dopant material and a P-type host material.

The common layers may include a first common layer 221, a second common layer 223, a third common layer 225, a fourth common layer 227, a fifth common layer 229, and a sixth common layer 2211. The fifth common layer 229 and the first common layer 221 may have a same stacked structure. The sixth common layer 2211 and the second common layer 223 may have a same stacked structure. For example, the fifth common layer 229 may include a hole injection layer HIL and a hole transport layer HTL, and the sixth common layer 2211 may include an electron transport layer ETL and an electron injection layer EIL.

In FIG. 7B, each of the second common layer 223, the fourth common layer 227, and the sixth common layer 2211 may include the electron transport layer ETL and the electron injection layer EIL. However, the disclosure is not limited thereto, and the second common layer 223, the fourth common layer 227, and the sixth common layer 2211 may not include the electron injection layer EIL.

In the embodiment, the hole injection layer HIL, the hole transport layer HTL, the first sub-emission layer EML1, the electron transport layer ETL, the electron injection layer EIL, the first sub-charge generation layer CGL1, the hole injection layer HIL, the hole transport layer HTL, the second sub-emission layer EML2, the electron transport layer ETL, the electron injection layer EIL, the second sub-charge generation layer CGL2, the hole injection layer HIL, the hole transport layer HTL, the third sub-emission layer EML3, the electron transport layer ETL, the electron injection layer EIL, and an opposite electrode 230 may be stacked one another (e.g., stacked in sequence) on a pixel electrode 210.

In FIG. 7A, two sub-emission layers (e.g., the first and second sub-emission layers EML1 and EML2) of the organic light-emitting diode may be stacked each other. However, the disclosure is not limited thereto. Various modifications are possible. For example, three or more sub-emission layers (e.g., the first to third sub-emission layers EML1, EML2, and EML3) may be stacked one another as illustrated in FIG. 7B, or only one sub-emission layer (e.g., a first sub-emission layer EML1) may be included as illustrated in FIG. 7C.

Referring to FIG. 7C, detailed description of a stacked structure of an organic light-emitting diode, according to another embodiment, is provided as follows. An intermediate layer 220 may be disposed between a pixel electrode 210 and an opposite electrode 230. The intermediate layer 220 may include a first common layer 221, an emission layer 222″ (e.g., the first sub-emission layer EML1), and a second common layer 223. For example, a hole injection layer HIL, a hole transport layer HTL, the emission layer 222″ (e.g., the first sub-emission layer EML1), an electron transport layer ETL, an electron injection layer EIL, and the opposite electrode 230 may be stacked one another (e.g., stacked in sequence) on the pixel electrode 210. In the embodiment of FIG. 7C, a charge generation layer (e.g., the charge generation layer 224 of FIG. 7A) may not be stacked.

In case that emission layers are stacked each other as in the embodiments of FIGS. 7A and 7B, a charge generation layer (e.g., the charge generation layer 224 of FIG. 7A or the charge generation layer 228 of FIG. 7B) may be disposed between the emission layers (e.g., the first and second sub-emission layers EML1 and EML2 of the emission layer 222 of FIG. 7A or the first to third sub-emission layers EML1, EML2, and EML3 of the emission layer 222 of FIG. 7B). A leakage current may be generated by the charge generation layer, and adjacent organic light-emitting diodes may emit light. For example, in the embodiment of FIG. 4, in case that a common voltage ELVSS (e.g., refer to FIG. 2) and a driving voltage are applied to cause the first organic light-emitting diode OLED1 to emit light, a current (e.g., the leakage current) may flow to the second organic light-emitting diode OLED2 through the charge generation layer 224 (or the charge generation layer 228). Thus, the second organic light-emitting diode OLED2 may emit fine light (e.g., dim light or glimmer).

In the embodiment of FIG. 7C, the organic light-emitting diode may not include the charge generation layer 224 (or the charge generation layer 228). However, a leakage current may still flow through the common layers, for example, the first common layer 221.

FIG. 8 is a schematic cross-sectional view of a display apparatus 1 according to an embodiment and is a schematic cross-sectional view illustrating an example of a cross-section of the display apparatus 1 of FIG. 3 taken along line I-I′ of FIG. 3. In FIG. 8, detailed description of the same constituent elements as those in FIG. 4 is omitted.

In FIG. 8, an organic light-emitting diode may have a stacked structure of the organic light-emitting diodes illustrated in FIG. 7A. However, the disclosure is not limited thereto. For example, the organic light-emitting diodes according to an embodiment may have a stacked structure of the organic light-emitting diodes illustrated in FIG. 7B or 7C.

Referring to FIGS. 7A and 8, each of the organic light-emitting diodes may include a lower emission layer and an upper emission layer, which overlap each other in a plan view. The lower emission layer of the organic light-emitting diode may correspond to the first sub-emission layer EML1 of FIG. 7A, and the upper emission layer may correspond to the second sub-emission layer EML2 of FIG. 7A.

For example, the first organic light-emitting diode OLED1 may include a first lower emission layer 222L-1 and a first upper emission layer 222U-1. The first upper emission layer 222U-1 may be disposed on the first lower emission layer 222L-1 and overlap the first lower emission layer 222L-1 in a plan view. For example, the first emission layer 222-1 may include the first lower emission layer 222L-1 and the first upper emission layer 222U-1. The first lower emission layer 222L-1 may be disposed on the first pixel electrode 210-1, and the first upper emission layer 222U-1 may be disposed on the first lower emission layer 222L-1.

The second organic light-emitting diode OLED2 may include a second lower emission layer 222L-2 and a second upper emission layer 222U-2. The second upper emission layer 222U-2 may be disposed on the second lower emission layer 222L-2 and overlap the second lower emission layer 222L-2 in a plan view. For example, the second emission layer 222-2 may include the second lower emission layer 222L-2 and the second upper emission layer 222U-2. The second lower emission layer 222L-2 may be disposed on the second pixel electrode 210-2, and the second upper emission layer 222U-2 may be disposed on the second lower emission layer 222L-2.

The third organic light-emitting diode OLED3 may include a third lower emission layer 222L-3 and a third upper emission layer 222U-3. The third upper emission layer 222U-3 may be disposed on the third lower emission layer 222L-3 and overlap the third lower emission layer 222L-3 in a plan view. For example, the third emission layer 222-3 may include the third lower emission layer 222L-3 and the third upper emission layer 222U-3. The third lower emission layer 222L-3 may be disposed on the third pixel electrode 210-3, and the third upper emission layer 222U-3 may be disposed on the third lower emission layer 222L-3.

Each of the first emission layer 222-1, the second emission layer 222-2, and the third emission layer 222-3 may correspond to the emission layer 222 of FIG. 7A.

The intermediate layer 220 of each of the organic light-emitting diodes may include a charge generation layer 224 and common layers. For example, the first organic light-emitting diode OLED1 may include a first pixel electrode 210-1, a 1^{st}-1 common layer 221-1 (e.g., a 1-1-th common layer 221-1), a first lower emission layer 222L-1, a 2^{nd}-1 common layer 223-1 (e.g., a 2-1-th common layer 223-1), a first charge generation layer 224-1, a 3^{rd}-1 common layer 225-1 (e.g., a 3-1-th common layer 225-1), a first upper emission layer 222U-1, and a 4th-1 common layer 227-1 (e.g., a 4-1-th common layer 227-1), which are stacked one another (e.g., stacked in sequence). The second organic light-emitting diode OLED2 may include a second pixel electrode 210-2, a 1^{st}-2 common layer 221-2 (e.g., a 1-2-th common layer 221-2), a second lower emission layer 222L-2, a 2^{nd}-2 common layer 223-2 (e.g., a 2-2-th common layer 223-2), a second charge generation layer 224-2, a 3^{rd}-2 common layer 225-2 (e.g., a 3-2-th common layer 225-2), a second upper emission layer 222U-2, and a 4th-2 common layer 227-2 (e.g., a 4-2-th common layer 227-2), which are stacked one another (e.g., stacked in sequence). The third organic light-emitting diode OLED3 may include a third pixel electrode 210-3, a 1^{st}-3 common layer 221-3 (e.g., a 1-3-th common layer 221-3), a third lower emission layer 222L-3, a 2^{nd}-3 common layer 223-3 (e.g., a 2-3-th common layer 223-3), a third charge generation layer 224-3, a 3^{rd}-3 common layer 225-3 (e.g., a 3-3-th common layer 225-3), a third upper emission layer 222U-3, and a 4th-3 common layer 227-3 (e.g., a 4-3-th common layer 227-3), which are stacked one another (e.g., stacked in sequence).

Each of the 1^{st}-1 common layer 221-1, the 1^{st}-2 common layer 221-2, and the 1^{st}-3 common layer 221-3 may correspond to the first common layer 221 of FIG. 7A. Each of the 2^{nd}-1 common layer 223-1, the 2^{nd}-2 common layer 223-2, and the 2^{nd}-3 common layer 223-3 may correspond to the second common layer 223 of FIG. 7A. Each of the 3^{rd}-1 common layer 225-1, the 3^{rd}-2 common layer 225-2, and the 3^{rd}-3 common layer 225-3 may correspond to the third common layer 225 of FIG. 7A. Each of the 4th-1 common layer 227-1, the 4th-2 common layer 227-2, and the 4th-3 common layer 227-3 may correspond to the fourth common layer 227 of FIG. 7A. Each of the first charge generation layer 224-1, the second charge generation layer 224-2, and the third charge generation layer 224-3 may correspond to the charge generation layer 224 of FIG. 7A.

The 1^{st}-1 common layer 221-1, the 1^{st}-2 common layer 221-2, and 1^{st}-3 common layer 221-3 each corresponding to the first common layer 221 may be simultaneously formed of a same material through a same process. The 2^{nd}-1 common layer 223-1, the 2^{nd}-2 common layer 223-2, and the 2^{nd}-3 common layer 223-3 each corresponding to the second common layer 223 may be simultaneously formed of a same material through a same process. The 3^{rd}-1 common layer 225-1, the 3^{rd}-2 common layer 225-2, and the 3^{rd}-3 common layer 225-3 each corresponding to the third common layer 225 may be simultaneously formed of a same material through a same process. The 4th-1 common layer 227-1, the 4th-2 common layer 227-2, and the 4th-3 common layer 227-3 each corresponding to the fourth common layer 227 may be simultaneously formed of a same material through a same process.

In case that the display apparatus has a high resolution, the gap between adjacent pixels may be relatively small. In case that the gap between pixels becomes smaller, a leakage current flowing between adjacent pixels through the common layers included in the intermediate layer may increase. For example, a leakage current may flow between adjacent pixels through the first common layer or the charge generation layer. An embodiment may include the metal partition wall MW and may prevent a leakage current by applying a voltage (e.g., a certain or selectable voltage) to the metal partition wall MW.

According to an embodiment, the metal partition wall MW, the intermediate layer 220 (e.g., the first intermediate layer 220-1, the second intermediate layer 220-2, and the third intermediate layer 220-3), and the opposite electrode 230 may be sequentially stacked one another on the pixel defining layer 215. For example, the intermediate layer 220 may be disposed between the metal partition wall MW and the opposite electrode 230. A first voltage equal to or lower than a second voltage may be applied to the metal partition wall MW. The second voltage may be a voltage (e.g., a common voltage) applied to the opposite electrode 230. Since an auxiliary capacitor Cap_M (e.g., refer to FIG. 4) is formed between the metal partition wall MW and the opposite electrode 230, RC delay may increase. Accordingly, response of adjacent pixels due to a leakage current may be reduced.

FIG. 9 is a schematic cross-sectional view of the display apparatus 1 according to an embodiment and is a schematic cross-sectional view illustrating an example of a cross-section of the display apparatus 1 of FIG. 3 taken along line I-I′ of FIG. 3. In FIG. 9, detailed description of the same constituent elements as those in FIG. 4 is omitted.

Referring to FIG. 9, an inorganic insulating layer IL may cover a portion of a metal partition wall MW. The inorganic insulating layer IL may be disposed between the metal partition wall MW and an intermediate layer 220. The inorganic insulating layer IL may separate at least a portion of an upper surface US and/or at least a portion of a side surface SS of the metal partition wall MW from the intermediate layer 220. In FIG. 9, since the inorganic insulating layer IL exposes at least a portion of the upper surface US of the metal partition wall MW and covers the side surface SS of the metal partition wall MW, the intermediate layer 220 may be in direct contact with the upper surface US of the metal partition wall MW and may not be in contact with the side surface SS of the metal partition wall MW. However, embodiments are not limited thereto. The inorganic insulating layer IL may cover only a portion of the side surface SS of the metal partition wall MW, and the intermediate layer 220 may be in contact with an entire area of the upper surface US and a portion of the side surface SS of the metal partition wall MW. In other embodiments, the inorganic insulating layer IL may cover the upper surface US of the metal partition wall MW and expose the side surface SS of the metal partition wall MW. Thus, the intermediate layer 220 may be in contact only with the side surface SS of the metal partition wall MW. Thus, the arrangement of the inorganic insulating layer IL may be adjusted, and a portion at which the metal partition wall MW and the intermediate layer 220 are in direct contact with each other may be designated (or may be changed).

Referring to FIG. 9, the metal partition wall MW may have a multilayer structure including metal layers stacked each other on a pixel defining layer 215. For example, the metal partition wall MW may include a first metal layer M1, a second metal layer M2, and a third metal layer M3, as illustrated in FIG. 9. For example, the first to third metal layers M1, M2, and M3 may have different materials from one another. In an embodiment, the first metal layer M1 may include a material that is different from a material of the second metal layer M2 and/or the third metal layer M3. The second metal layer M2 may include a material that is different from a material of the first metal layer M1 and/or the third metal layer M3. The third metal layer M3 may include a material that is different from a material of the first metal layer M1 and/or the second metal layer M2.

In an embodiment, one of the first to third metal layers M1, M2, and M3 may include a material that causes galvanic corrosion with a pixel electrode 210. According to an embodiment, the inorganic insulating layer IL may cover a surface of the metal layer and prevent defects caused by corrosion in galvanic corrosion. For example, the second metal layer M2 may include aluminum (Al) and the pixel electrode 210 may include indium tin oxide (ITO). Since the inorganic insulating layer IL covers the side surface SS of the metal partition wall MW including the surface of the second metal layer M2, as illustrated in FIG. 9, galvanic corrosion between the second metal layer M2 and the pixel electrode 210 may be prevented.

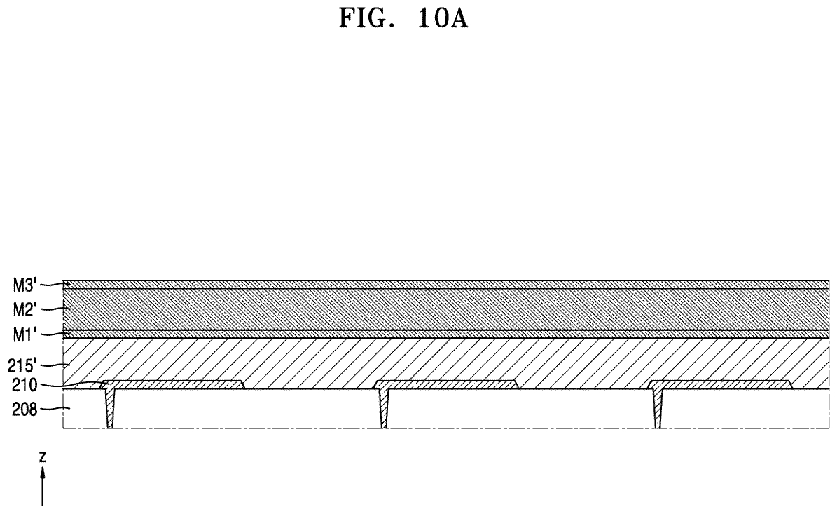

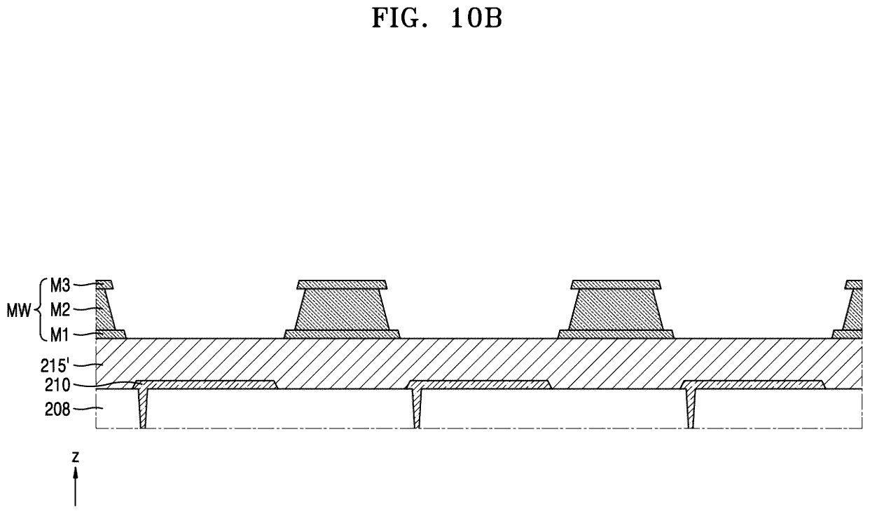

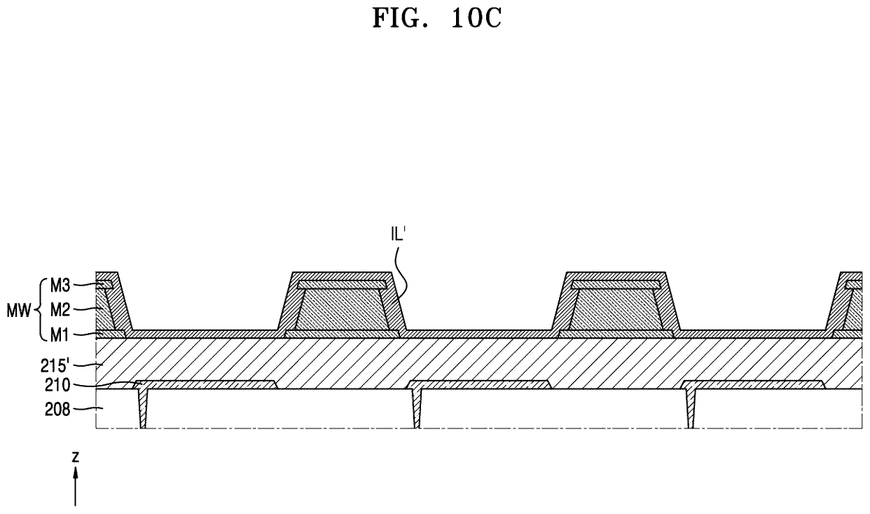

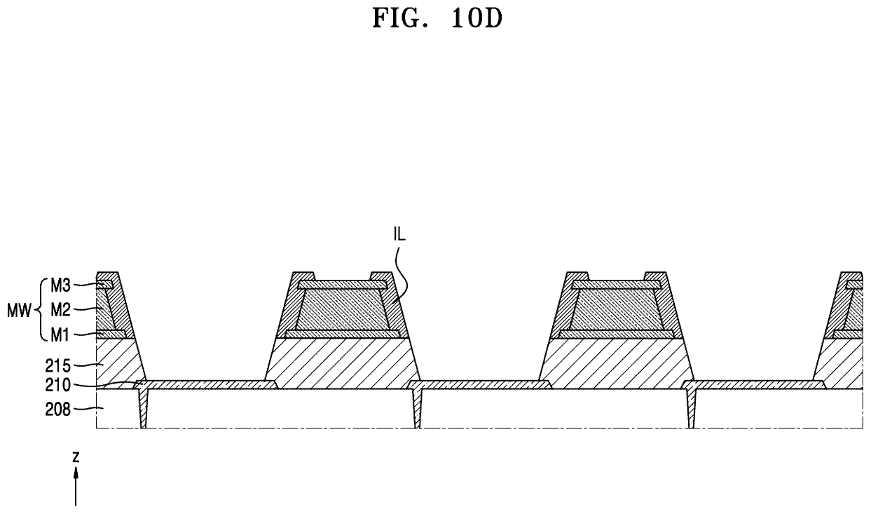

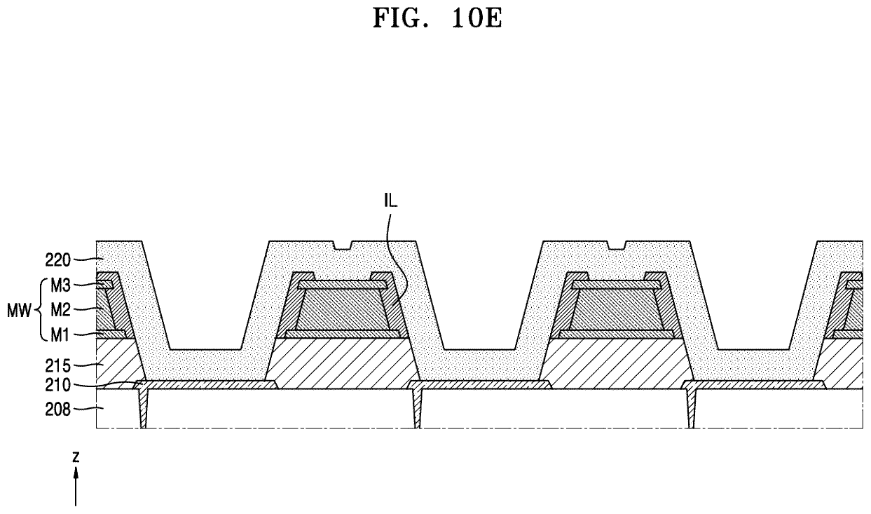

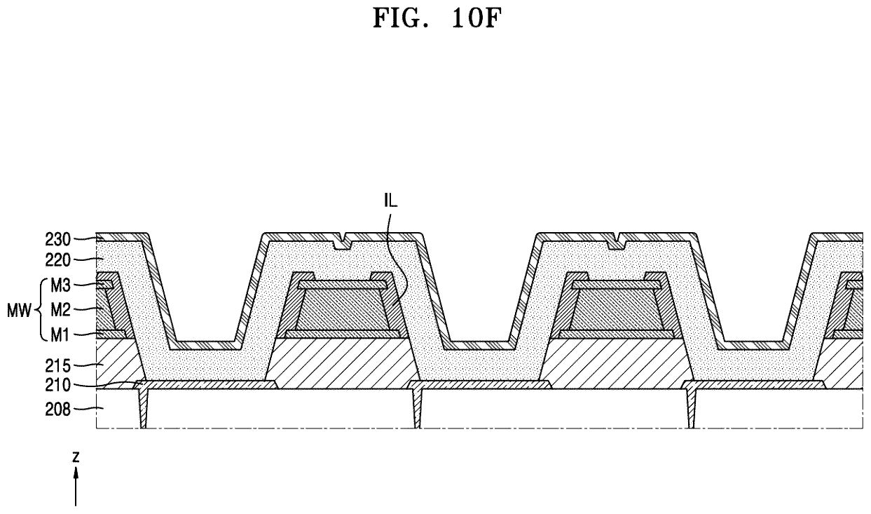

FIGS. 10A to 10F are schematic cross-sectional views for describing a process of manufacturing a display apparatus according to an embodiment. FIGS. 10A to 10F schematically illustrate the manufacturing process of the embodiment of FIG. 9.

Referring to FIG. 10A, after a pixel electrode 210 is formed on a planarization layer 208, a preliminary pixel defining layer 215′ may cover an entire area of the pixel electrode 210. A first preliminary metal layer M1′, a second preliminary metal layer M2′, and a third preliminary metal layer M3′ may be sequentially formed on the preliminary pixel defining layer 215′.

Referring to FIG. 10B, portions of the first preliminary metal layer M1′ (e.g., refer to FIG. 10A), the second preliminary metal layer M2′ (e.g., refer to FIG. 10A), and the third preliminary metal layer M3′ (e.g., refer to FIG. 10A) may be removed through an etching process. The etching process may be dry etching or wet etching. Accordingly, the first preliminary metal layer M1′ may form a first metal layer M1 of a metal partition wall MW, the second preliminary metal layer M2′ may form a second metal layer M2 of the metal partition wall MW, and the third preliminary metal layer M3′ may form a third metal layer M3 of the metal partition wall MW. In an embodiment, the second preliminary metal layer M2′ may include a metal material that is different from a metal material of the first preliminary metal layer M1′ and the third preliminary metal layer M3′. For example, the first to third preliminary metal layers M1′, M2′, and M3′ may have different materials from one another. Accordingly, after the etching process, the side surface of the metal partition wall MW may not be flat.

Referring to FIG. 10C, an inorganic layer IL′ may be formed on the preliminary pixel defining layer 215′ and the metal partition wall MW. The inorganic layer IL′ may be continuously disposed on metal partition walls (or banks) MW.

Referring to FIGS. 10C and 10D, the inorganic layer IL′ and the preliminary pixel defining layer 215′ may be etched through an etching process, and an inorganic insulating layer IL and a pixel defining layer 215 may be formed. The etching process may be dry etching and may be performed on the inorganic layer IL′ and the preliminary pixel defining layer 215′. Accordingly, the inorganic insulating layer IL and the pixel defining layer 215 may be formed simultaneously. In case that the inorganic insulating layer IL and the pixel defining layer 215 are formed simultaneously, the inorganic insulating layer IL may be located only on the upper side of the pixel defining layer 215. A portion of the inorganic insulating layer IL on the metal partition wall MW may be removed through an etching process.

Referring to FIG. 10E, an intermediate layer 220 may be formed on the inorganic insulating layer IL. As described above, the intermediate layer 220 may include common layers and an emission layer. A hole injection layer HIL (e.g., refer to FIG. 7A) and/or a hole transport layer HTL (e.g., refer to FIG. 7B) in the intermediate layer 220 may be in direct contact with the metal partition wall MW.

Referring to FIG. 10F, an opposite electrode 230 may be disposed on the intermediate layer 220. The opposite electrode 230 may be continuously disposed on metal partition walls (or banks) MW. In an embodiment, a first voltage may be applied to the metal partition wall MW, and a second voltage equal to or higher than the first voltage may be applied to the opposite electrode 230. The second voltage may be a common voltage ELVSS (e.g., refer to FIG. 2).

For convenience, the display apparatus including the organic light-emitting diode as the display element has been described. However, embodiments may be applied to various types of display apparatuses, such as a liquid crystal display, an electrophoretic display, and an inorganic electroluminescence (EL) display.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
a pixel electrode disposed on a substrate;
a pixel defining layer having an opening exposing a central portion of the pixel electrode;
an electrically conductive partition wall disposed on the pixel defining layer and having a height of about 500 Å or greater;
an intermediate layer disposed on the pixel electrode and comprising:
an emission layer; and
a plurality of common layers; and
an opposite electrode disposed on the intermediate layer,
wherein at least a portion of the intermediate layer is in direct contact with at least a portion of the electrically conductive partition wall.

2. The display apparatus of claim 1, wherein, in a plan view, the electrically conductive partition wall surrounds the opening of the pixel defining layer.

3. The display apparatus of claim 1, wherein the electrically conductive partition wall receives a voltage equal to or lower than a voltage applied to the opposite electrode.

4. The display apparatus of claim 1, wherein the electrically conductive partition wall has a trapezoidal cross-sectional shape.

5. The display apparatus of claim 1, wherein an area of an upper surface of the electrically conductive partition wall is smaller than an area of a lower surface of the electrically conductive partition wall.

6. The display apparatus of claim 1, further comprising:
an inorganic insulating layer covering a portion of the electrically conductive partition wall and arranged between the electrically conductive partition wall and the intermediate layer.

7. The display apparatus of claim 6, wherein
the electrically conductive partition wall comprises a plurality of metal layers sequentially stacked each other on the pixel defining layer,
the inorganic insulating layer covers at least a portion of a side surface of the electrically conductive partition wall, and
at least some of the plurality of common layers are in direct contact with at least a portion of an upper surface of the electrically conductive partition wall.

8. The display apparatus of claim 7, wherein
the pixel electrode includes indium tin oxide (ITO), and
at least some of the plurality of metal layers include aluminum (Al).

9. The display apparatus of claim 1, wherein
the emission layer comprises:
a lower emission layer; and
an upper emission layer overlapping the lower emission layer in a plan view, and
the intermediate layer further comprises a charge generation layer between the lower emission layer and the upper emission layer.

10. The display apparatus of claim 1, wherein
the electrically conductive partition wall comprises a metal partition wall, and
the metal partition wall includes at least one of molybdenum (Mo), titanium (Ti), and aluminum (Al).

11. A display apparatus comprising:
a first pixel electrode disposed on a substrate;
a second pixel electrode spaced apart from the first pixel electrode on the substrate;
a pixel defining layer having:
a first opening exposing a central portion of the first pixel electrode; and
a second opening exposing a central portion of the second pixel electrode;
an electrically conductive partition wall arranged between the first opening and the second opening, on the pixel defining layer, and receiving a first voltage;
a plurality of common layers disposed on the first pixel electrode and the second pixel electrode; and
an opposite electrode disposed on the plurality of common layers and receiving a second voltage equal to or higher than the first voltage,
wherein the electrically conductive partition wall is in direct contact with a hole injection layer or a hole transport layer, from among the plurality of common layers.

12. The display apparatus of claim 11, wherein the electrically conductive partition wall has a forward tapered cross-sectional shape.

13. The display apparatus of claim 11, wherein the electrically conductive partition wall has a height of about 500 Å or greater.

14. The display apparatus of claim 11, wherein, in a plan view, the electrically conductive partition wall surrounds each of the first opening and the second opening.

15. The display apparatus of claim 11, further comprising:
a first lower emission layer disposed on the first pixel electrode;
a second lower emission layer disposed on the second pixel electrode;
a first upper emission layer disposed on the first lower emission layer; and
a second upper emission layer disposed on the second lower emission layer.

16. The display apparatus of claim 15, wherein
the plurality of common layers comprise:
a 1^{st}-1 common layer disposed below the first lower emission layer; and
a 1^{st}-2 common layer disposed below the second lower emission layer, and
the 1^{st}-1 common layer and the 1^{st}-2 common layer are integral with each other.

17. The display apparatus of claim 15, further comprising:
a first charge generation layer between the first lower emission layer and the first upper emission layer; and
a second charge generation layer between the second lower emission layer and the second upper emission layer.

18. The display apparatus of claim 11, wherein the electrically conductive partition wall comprises a plurality of metal layers sequentially stacked each other on the pixel defining layer.

19. The display apparatus of claim 18, further comprising:
an inorganic insulating layer covering the electrically conductive partition wall and exposing at least a portion of an upper surface or a side surface of the electrically conductive partition wall.

20. The display apparatus of claim 11, wherein
the electrically conductive partition wall comprises a metal partition wall, and
the metal partition wall includes at least one of molybdenum (Mo), titanium (Ti), and aluminum (Al).
